(19) United States
(12) Patent Application Publication
(10) Pub. No.: US 2026/0252145 A1
(43) Pub. Date: Aug. 27, 2026

(54) ELECTRONIC APPARATUS

(71) Applicant: LENOVO JAPAN LLC, YOKOHAMA (JP)

(72) Inventors: Tatsuya Ushioda, YOKOHAMA (JP); Kazuya Tatsuno, YOKOHAMA (JP)

(73) Assignee: LENOVO JAPAN LLC, YOKOHAMA (JP)

(21) Appl. No.: 19/290,672

(22) Filed: Aug. 5, 2025

(30) Foreign Application Priority Data
Feb. 26, 2025 (JP) 2025029248

(51) Int. Cl. G06F 1/16; H05K 5/02

(52) U.S. Cl. CPC G06F 1/1656; G06F 1/1681; H05K 5/0234

(57) ABSTRACT

An electronic apparatus includes a leg partially protruding from a bottom face of a chassis, an outer portion constituting the bottom face and an inner portion in the chassis. The leg includes: a leg body protruding from a leg opening of the outer portion and includes an elastic material at least at the surface; and a flange protrudes in two opposing directions within the chassis, and is between the inner portion and the outer portion. The leg has a core integral with the rigid flange of the flange. The core is inside the leg body and protrudes from the leg opening.

### BACKGROUND OF THE INVENTION

### Field of the Invention

The present invention relates to an electronic apparatus having a leg on the bottom face of the chassis.

### Description of the Related Art

Electronic apparatuses such as a laptop PC are provided with legs on the bottom face of the chassis. These legs are made of an elastic material such as rubber, which act for anti-slip and as a shock absorber. The legs may be subjected to a relatively large external force, and thus they need to be mounted with a sufficient strength. Japanese Unexamined Patent Application Publication No. 2023-084008 describes an electronic apparatus whose legs include rubber and a core, and each core has a protrusion that is designed to pass through the hole in the bottom cover, and then the protrusion is heat-welded inside the chassis to be deformed into a disk shape. Then the bottom cover is caught between a part of the core outside the chassis and the thermally deformed disk-shaped part, so that the leg is fixed. Another means of securing the legs is to screw the legs to the bottom cover.

### SUMMARY OF THE INVENTION

The electronic apparatus described in Japanese Unexamined Patent Application Publication No. 2023-084008 is configured to catch the bottom cover with the core at the inside and outside of the chassis. That is, to keep a sufficient strength for the legs, the legs need to have a certain degree of size and area also at the outside of the chassis. When screws are used to fasten the legs to the bottom cover, the screws need to be relatively large and long to keep a sufficient strength. Therefore, these fixing means makes the legs larger than the size that is necessary for the original function of the legs, which are unfavorable from the standpoint of design.

In view of the above problem, the present invention aims to provide an electronic apparatus that has a small part of the leg exposed outside the chassis while keeping the strength.

To solve the above-described problems and achieve the aim, an electronic apparatus according to the first aspect of the present invention includes: a leg partially protruding from the bottom face of the chassis; a bottom plate defining the bottom face; and a pressing member disposed in the chassis. The leg includes: a leg body protruding from the bottom plate through a leg opening that the bottom plate has; a leg body including an elastic material at least at a surface; and a flange including a rigid material, protruding in at least two opposing directions within the chassis, and being caught between the bottom plate and the pressing member.

The above-described aspect of the present invention has a small part of the leg exposed outside the chassis while keeping the strength.

### BRIEF DESCRIPTION OF THE DRAWINGS

FIG. 1 is a schematic top plan view of an electronic apparatus according to one embodiment.

FIG. 2 is a perspective view of the rear edge of the chassis viewed from the bottom face.

FIG. 3 is an exploded perspective view of the chassis.

FIG. 4 is a cross-sectional side view of a leg opening, a leg and their surroundings.

FIG. 5 is an exploded perspective view of a leg opening, a leg and their surroundings.

FIG. 6 is a perspective view of the leg.

FIG. 7 is an exploded perspective view of the leg.

FIG. 8 is an exploded perspective view of a leg opening, a leg and their surroundings in an electronic apparatus according to a modified example.

### DETAILED DESCRIPTION OF THE INVENTION

The following describes an electronic apparatus according to one embodiment of the present invention in details, with reference to the drawings. The present invention is not limited to the following embodiment.

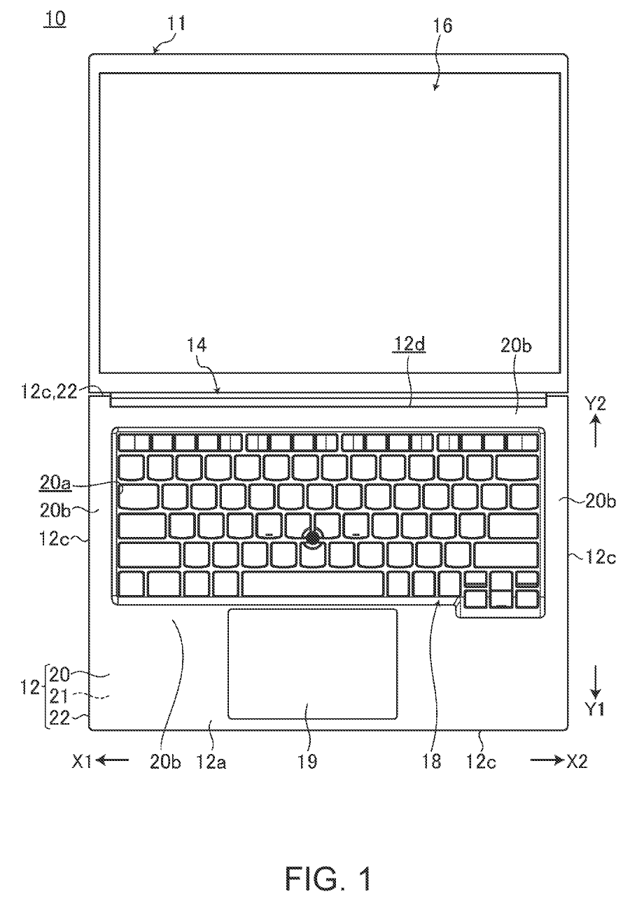

FIG. 1 is a schematic top plan view of an electronic apparatus 10 according to one embodiment. As illustrated in FIG. 1, the electronic apparatus 10 of the present embodiment is a clamshell-type laptop PC. The electronic apparatus 10 includes a lid 11 and a chassis 12 that are relatively rotatably connected with a hinge 14. The present embodiment exemplifies the electronic apparatus 10 that is a laptop PC, which may be of various types other than the laptop PC, including a tablet PC, a smartphone, and a portable game machine.

The lid 11 is a thin, flat, box-shaped chassis. The lid 11 has a display 16 mounted thereon. The display 16 is an organic EL display or a liquid crystal display, for example.

The chassis 12 is a thin, flat box. The chassis 12 has a keyboard unit 18 and a touchpad 19 on the top face 12a. The following describes the chassis 12 and elements mounted on the chassis with reference to the direction viewed from the operator using the keyboard unit 18, where the width directions (left and right) of the chassis 12 are referred to as X1 and X2 directions, the depth directions (front and rear) of the chassis 12 are referred to as Y1 and Y2 directions, and the thickness directions of the chassis 12 (top and bottom) are referred to as Z1 and Z2 directions. X1 and X2 directions may be collectively referred to as X direction, and Y1 and Y2 directions and Z1 and Z2 directions may also be referred to as Y direction and Z direction, respectively, in the same way. These directions are for convenience of explanation, and they may change depending on the operating state or the posture of the electronic apparatus 10 when it is placed.

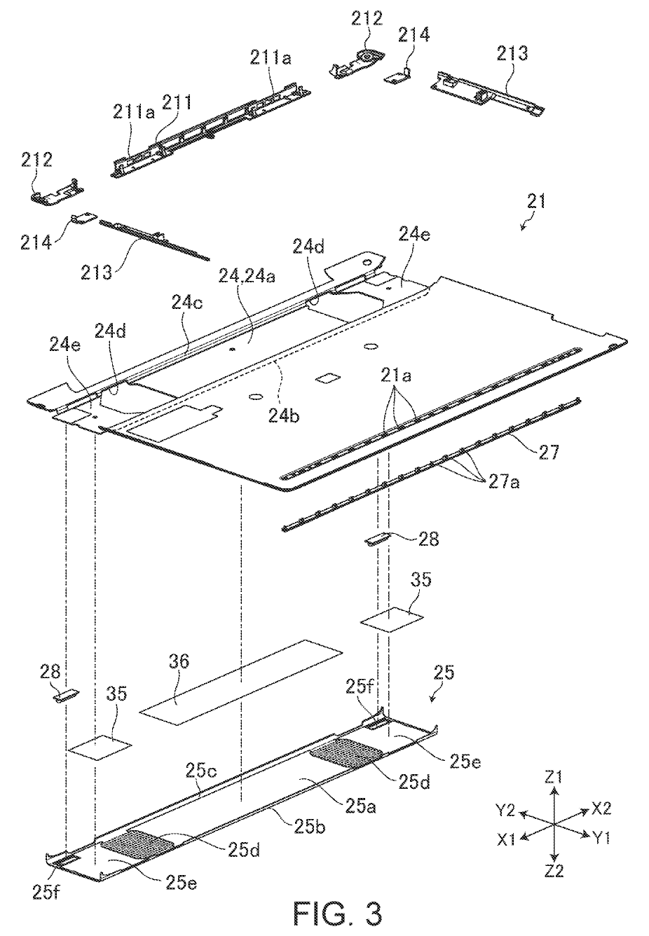

The chassis 12 has a plate member 20 defining the top face 12a, a bottom cover 21 defining the bottom face 12b, and a vertical wall 22 defining the four surrounding side faces 12c. The plate member 20 has a large rectangular opening 20a in which the keyboard unit 18 is placed. The periphery of the opening 20a defines a bezel 20b that surrounds the keyboard unit 18. The bottom cover 21 has a plate shape (see FIG. 3). As will be described later, the chassis 12 of this embodiment is provided with a protrusion 23 near the Y2 edge of the bottom cover 21. The vertical wall 22 stands between the four peripheral edges of the plate member 20 and the four peripheral edges of the bottom cover 21, and has a frame shape as a whole. The plate member 20 is formed, for example, by pressing a metal plate. The bottom cover 21 is prepared, for example, by molding of a resin material.

The hinge 14 is placed in a recessed hinge placement groove 12d located at the rear edge of the chassis 12, and connects the chassis 12 and the lid 11 together. The hinge 14 of this embodiment has a one-bar drop-down structure. The structure of hinge 14 may be other than this.

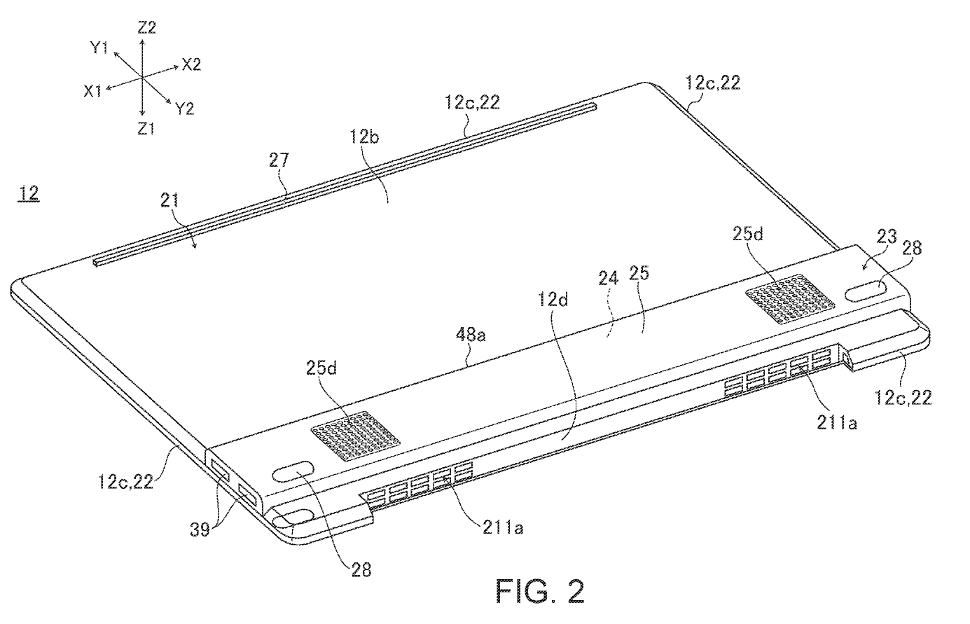

FIG. 2 is a perspective view of the rear edge of the chassis 12 viewed from the bottom face 12b. FIG. 3 is an exploded perspective view of the chassis 12. FIG. 3 omits the keyboard unit 18, the plate member 20, and internal components.

On the bottom face 12b of the chassis 12, the protrusion 23 protrudes downward. The protrusion 23 has a rectangular cylindrical shape that is long in X direction and flat in Z direction. The length of the protrusion 23 in X direction spans the entire width of the chassis 12 in X direction. The protrusion 23 is located immediately in front of the hinge placement groove 12d at a position closer to the Y2 edge in the front-rear direction (Y direction) of the bottom face 12b.

The protrusion 23 may have an input/output port 39 at each of its longitudinal ends (left and right end faces). Examples of the input/output port 39 include an input/output port conforming to the HDMI (registered trademark) standard, and an input/output port conforming to the USB 3.0 communication standard. This allows the electronic apparatus 10 to minimize the thickness of the chassis 12 while allowing the installation of the input/output ports 39, which requires a certain amount of height. The protrusion 23 also functions as a rear leg that raises the rear portion of the chassis 12 placed on a surface (placement surface) to place the apparatus (e.g., desk surface) higher than the front portion. This allows the keyboard unit 18 of the electronic apparatus 10 to be inclined downward toward the front when in use, improving its operability. Inside the protrusion 23, other units not shown, such as a motherboard, a module card, a fan, and a cooling module, may be placed.

The protrusion 23 includes an inner portion (pressing member) 24 that is a part of the bottom cover 21, and an outer portion (bottom plate) 25 that covers the inner portion 24. In other words, the bottom cover 21 is not exposed downward at the protrusion 23, and the outer portion 25 of the protrusion 23 defines the bottom face to be the bottom plate substantially. The front and rear walls of the protrusion 23 may have intake holes for fan.

The inner portion 24 has an inner flat plate 24a extending in X direction, and arc-shaped inner walls 24b and 24c at the front and rear of the inner flat plate 24a. The inner portion 24 has fan holes 24d at positions spaced apart on the left and right. The fan holes 24d and intake holes 25d, which will be described later, are holes for intake of air by the fan. The two fan holes 24d are spaced apart from each other, and between each fan hole 24d and the left or right edge of the bottom cover 21, the inner portion 24 has a space 24e of appropriate width. This space 24e is for placing a housing of the input/output port 39, for example.

To the bottom cover 21, a rear wall frame 211, two rear corner frames 212, two horizontal frames 213, two port dividers 214, and others are attached. The rear wall frame 211 is attached to the rear edge of the bottom cover 21 and defines part of the hinge placement groove 12d. The rear wall frame 211 has an exhaust hole 211a. The exhaust hole 211a is for exhausting air from the fan. The port divider 214 is attached to each space 24e and divides the multiple input/output ports 39.

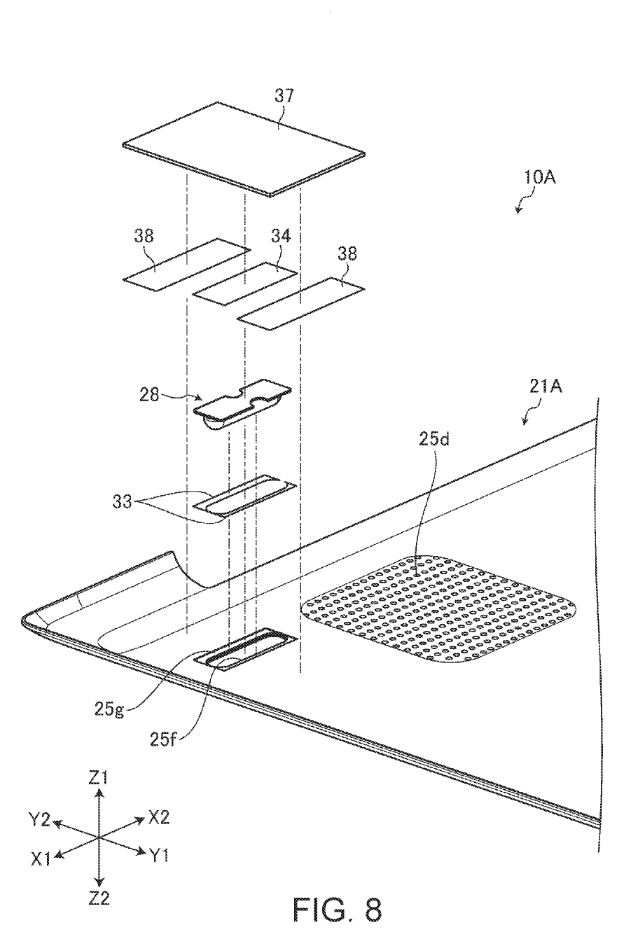

To the bottom cover 21, a front leg 27 is attached near the front edge. The front leg 27 is long and thin in X direction, and protrudes slightly downward. The front leg 27 have a plurality of posts 27a, which are inserted into post holes 21a in the bottom cover 21 and are welded thereto. Note here, instead of the front leg 27, a leg 28 may be provided near the front edge of the bottom cover 21 in a manner similar to that illustrated in FIG. 8.

The outer portion 25 is obtained, for example, by pressing a metal plate. The outer portion 25 has an outer flat plate 25a that covers the bottom face of the inner flat plate 24a, and outer walls 25b and 25c that cover the front and rear of the inner walls 24b and 24c. The outer portion 25 has an intake hole 25d at a position corresponding to the fan hole 24d. The intake hole 25d includes many small holes. Between each intake hole 25d and the left or right edge, the outer portion 25 has a space 25e of appropriate width. The space 24e and the space 25e overlap each other. The outer portion 25 has a leg opening 25f near the rear end of each of the left and right spaces 25e. Each leg opening 25f is appropriately narrow, long in X direction (first direction), and has an oval shape with semicircular ends.

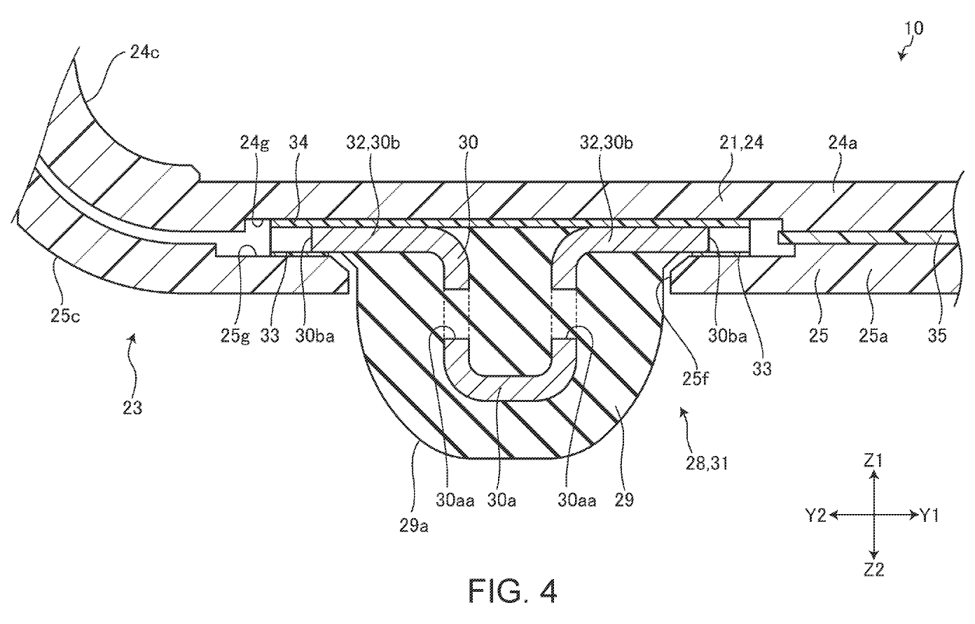

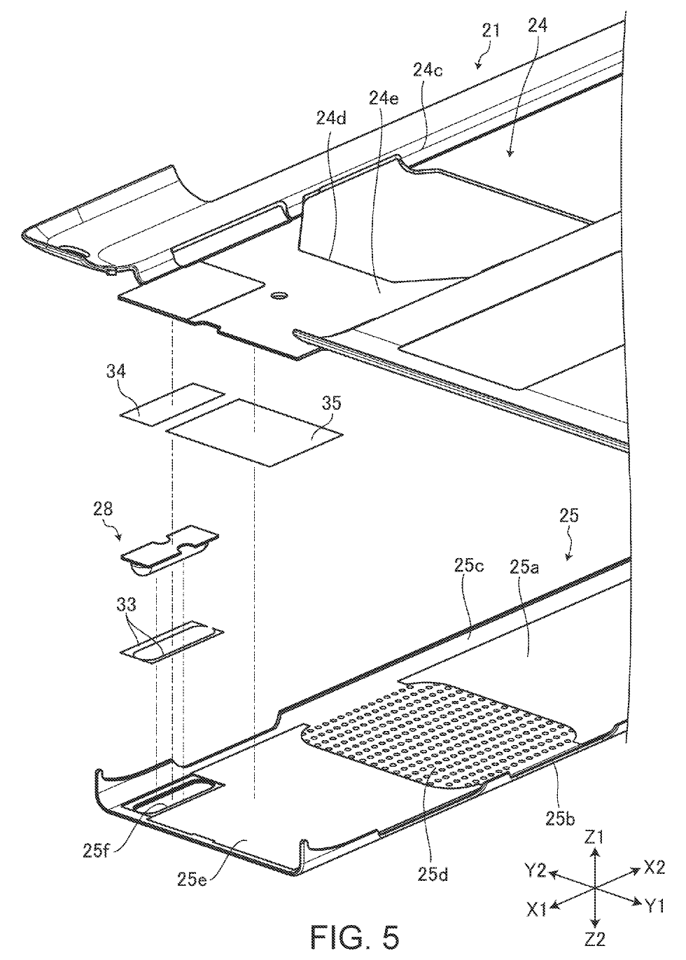

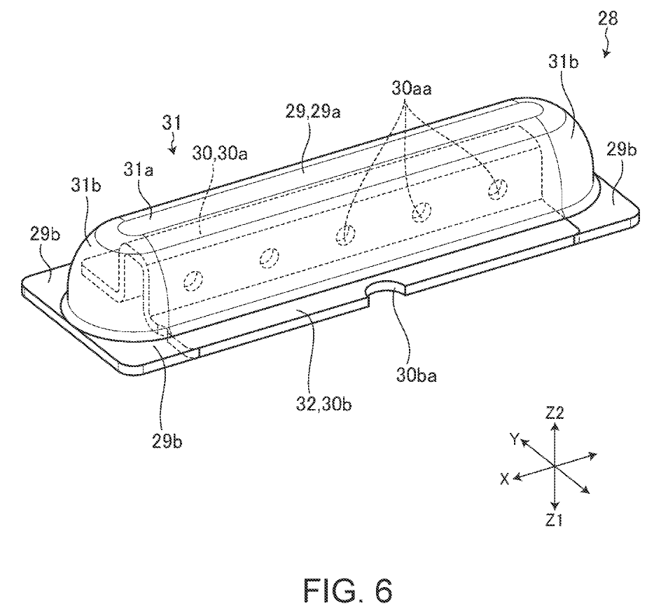

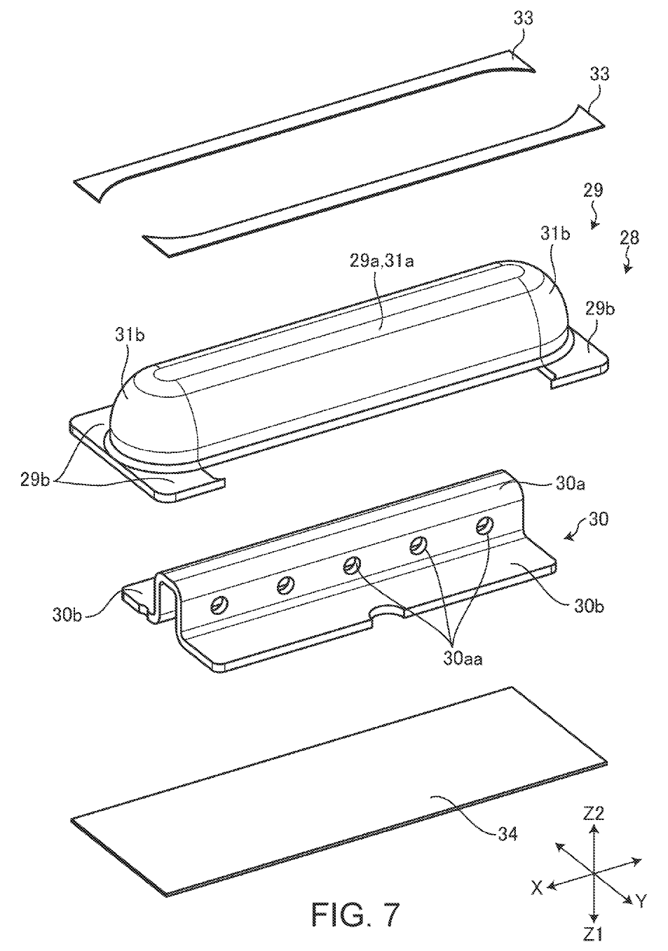

FIG. 4 is a cross-sectional side view of the leg opening 25f, the leg 28 and their surroundings. FIG. 5 is an exploded perspective view of the leg opening 25f, the leg 28 and their surroundings. FIG. 6 is a perspective view of the leg 28. FIG. 7 is an exploded perspective view of the leg 28. To facilitate understanding, the resin elastic material 29 in FIGS. 6 and 7 has contour lines described, which do not actually exist.

The leg opening 25f is surrounded by a shallow countersink 25g. Each space 24e has a shallow countersink 24g at a position facing the countersink 25g. The leg opening 25f receives a leg body 31 of the leg 28 that protrudes downward. Each leg 28 serves as a rear leg and, together with the front leg 27 described above, supports the chassis 12 on the placement surface. The legs 28 and the front leg 27 act for anti-slip and as a shock absorber. The protrusion 23 is slightly raised from the placement surface by the legs 28, so that the intake holes 25d are not blocked.

The following describes the legs 28 in further detail.

Each leg 28 includes the resin elastic material 29 such as silicone rubber, and a bracket 30. The leg 28 is symmetrical front to back and left to right. The resin elastic material 29 has a suitable elasticity. The bracket 30 has a suitable thickness and is strong. The resin elastic material 29 and the bracket 30 are integrated together by insert molding. This means that these two cannot be separated basically, but are illustrated in a separated state in FIG. 7 for ease of understanding.

The bracket 30 is harder than the resin elastic material 29 and is typically made of a rigid material. The bracket 30 of this embodiment is formed by bending a metal plate made of stainless steel, for example. A rigid material such as polycarbonate may be used as a core 30a, depending on the specifications.

The bracket 30 includes the core 30a and two rigid flanges 30b that are integrated together. The core 30a is long in X direction, and has a U-shaped cross section that opens upward (toward the inside of the chassis). The core 30a has a width in Y direction and a width in Z direction that are substantially equal to each other. The core 30a has a plurality of holes 30aa in the front and rear walls, which facilitates injection of the resin elastic material during insert molding and makes it difficult to separate after molding. The cross section of the core 30a may be V-shaped or C-shaped.

The rigid flanges 30b protrude in Y1 direction and Y2 direction (second direction) from both ends of the upper opening of the U-shape of the core 30a. The width in Y direction of each rigid flange 30b is approximately equal to that of the core 30a. The rigid flange 30b has a semicircular cutout 30ba in the center of the edge for positioning. A pin protruding from the inner portion 24 fits into the semicircular cutout 30ba for positioning. FIG. 4 omits this pin.

The resin elastic material 29 has a dome 29a and an auxiliary flange 29b. The dome 29a houses the core 30a and constitutes the leg body 31 together with the core 30a. The leg body 31 has the basic functions of the leg 28, such as anti-slip and shock absorbing for the chassis 12. As described above, the leg opening 25f receives the leg body 31 that protrudes downward. The leg body 31 is sized and shaped to just fit into the leg opening 25f, and includes a semi-cylindrical portion 31a and spherical portions 31b on both ends. Each spherical portion 31b has a shape obtained by dividing a sphere into quarters. The amount of downward protrusion of the leg body 31 from the leg opening 25f is approximately half the width of the leg opening 25f in Y direction. The semi-cylindrical portion 31a is a downwardly convex semicircular shape, and its width in Y direction is approximately twice that of the core 30a.

The core 30a is placed inside the leg body 31 and protrudes from the leg opening 25f. The amount of downward protrusion of the core 30a from the leg opening 25f is approximately half the width of the core 30a in Z direction. Depending on design conditions such as the hardness of the resin elastic material 29, the core 30a may be made larger or smaller, or may be omitted. In other words, at least the surface of leg body 31 may be made of the resin elastic material 29.

Each auxiliary flange 29b protrudes in Y1 and Y2 directions from the spherical portion 31b and is continuous with the rigid flange 30b with the same thickness as the rigid flange 30b, defining an apparently integral flange 32. Note that the rigid flange 30b has a higher strength, and the auxiliary flange 29b is only auxiliary. The boundary between the flange 32 and the leg body 31 is smoothly connected in an arc shape. The rigid flange 30b is basically exposed at its top and bottom faces, but is permitted to be covered with a thin film during the process of insert molding into the resin elastic material 29.

The top face of the leg 28 is rectangular, and adhesive sheets 33 of the same size are attached to it. This top face then is brought to abut the countersink 25g via the adhesive sheets 33 for fixing. Adhesive sheets 34 of the same size are attached to the bottom faces of the two flanges 32. These faces then are brought to abut the countersinks 24g via the adhesive sheets 34 for fixing. These adhesive sheets 33 and 34 may be omitted for some conditions. The countersinks 24g and 25g contribute to suppress the thickness of this part in Z direction.

The space 24e of the inner portion 24 and the space 25e of the outer portion 25 are fixed together by a suitably wide heat-bonding sheet 35 (see FIG. 5). The heat-bonding sheet 35 is placed in the region forward of the leg opening 25f and the leg 28. The inner portion 24 and outer portion 25 are fixed together by a heat-bonding sheet 36 (see FIG. 3) in the relatively wide area between the two fan holes 24d. The heat-bonding sheet 36 is wider than the heat-bonding sheet 35. These heat-bonding sheets 35 and 36 are heated to strongly bond the inner portion 24 and the outer portion 25 together. The means for fixing the inner portion 24 and outer portion 25 is not limited to this. The rigid flange 30b is located close to the heat-bonding sheet 35, but is made of metal and is not affected by heating.

The legs 28 in the electronic apparatus 10 configured in this manner each have the leg body 31 protruding from the leg opening 25f and the flanges 32 including the rigid flange 30b protruding in the opposing Y1 and Y2 directions within the chassis 12 and caught between the inner portion 24 and the outer portion 25. This configuration keeps the legs 28 to be mounted strongly, and prevents the legs 28 from peeling off from the chassis 12. The protrusion 23 in this embodiment includes the outer portion 25 that constitutes the bottom plate, and the inner portion 24 that constitutes a pressing member for the flange 32. The rigid flanges 30b protruding in at least two opposing directions are favorably strong, but they may also protrude in four directions. The rigid flanges 30b are inside the chassis 12 and are not exposed, and thus the rigid flanges 30b that are larger to some extent do not affect the external design. The flanges 32 are more securely fixed to the inner portion 24 and the outer portion 25 by the adhesive sheets 33 and 34.

The leg body 31 protruding from the leg opening 25f does not have a function for fixing the leg 28, and thus its area when viewed from the bottom may be the same as or smaller than the leg opening 25f. In this way, the portion exposed to the outside of the chassis 12 is made compact, which is favorable from the design standpoint. The leg body 31 internally has the core 30a, which provides favorable strength and prevents collapse, particularly in Y direction. The core 30a is integral with the rigid flanges 30b and has even higher strength. The core 30a is U-shaped and has a moderately thick width in Y direction, which provides further strength and is suitable for insert molding with the bracket 30. The legs 28 are located on the left and right of the chassis 12, but may be one long piece, or may be three or more pieces.

FIG. 8 is an exploded perspective view of a leg opening 25f, a leg 28 and their surroundings in an electronic apparatus 10A according to a modified example. A bottom cover 21A in the electronic apparatus 10A corresponds to the above-mentioned bottom cover 21, and constitutes the bottom plate of the chassis 12. The electronic apparatus 10A does not have the protrusion 23 of the electronic apparatus 10. Therefore, the electronic apparatus 10A does not have the outer portion 25 and the inner portion 24.

The bottom cover 21A has two leg openings 25f. These leg openings 25f are located at approximately the same positions as the leg openings 25f in the above-mentioned bottom cover 21 in a plan view, and each have a leg 28 provided therein. The leg 28 and its surroundings are covered with a pressing member 37. The pressing member 37 is a plate having an appropriate size and strength. The flanges 32 of the leg 28 are caught and fixed by the pressing member 37 and the bottom cover 21A. The leg 28 is fixed more securely to the bottom cover 21A and the pressing member 37 by adhesive sheets 33 and 34. The pressing member 37 is fixed to the bottom cover 21A by a heat-bonding sheet 38. The pressing member 37 is for fixing the leg 28, but it does not have to be a dedicated member, and for example, the rear corner frame 212 may also be used for this purpose.

The present invention is not limited to the above-described embodiments, and can be modified freely without deviating from the scope of the present invention.

1. An electronic apparatus including a chassis having a top face and a bottom face, comprising:
a leg partially protruding from the bottom face of the chassis;
a bottom plate defining the bottom face; and
a pressing member in the chassis;
the leg including: a leg body protruding from the bottom plate through a leg opening in the bottom plate; the leg body of an elastic material at least at a surface thereof; and a flange of a rigid material, protruding in at least two opposing directions within the chassis, and disposed between the bottom plate and the pressing member.

2. The electronic apparatus according to claim 1, wherein
the chassis includes a bottom cover having an inner portion and an outer portion that covers the bottom face of the inner portion, wherein
the outer portion constitutes the bottom plate, and
the inner portion constitutes the pressing member.

3. The electronic apparatus according to claim 2, wherein
the inner portion and the outer portion constitute a protrusion that protrudes downward from the chassis.

4. The electronic apparatus according to claim 1, wherein
the leg body extends in a first direction, and the flange protrudes in a second direction perpendicular to the first direction.

5. The electronic apparatus according to claim 1, wherein
the leg has a core including a rigid material integral with the flange, wherein the core is inside the leg body and protrudes from the leg opening.

6. The electronic apparatus according to claim 5, wherein
the core is U-shaped, V-shaped, or C-shaped and has an opening toward an inside of the chassis, and the flange protrudes from both ends of the opening.
